(19) United States
(12) Patent Application Publication
(10) Pub. No.: US 2024/0075420 A1
(43) Pub. Date: Mar. 7, 2024

(54) Self-Validating Purification System with Automated Operational and Efficacy Testing

(71) Applicants: Terry L. Zarnowski, Fulton, NY (US); Karl D. Selander, Hopewell Junction, NY (US)

(72) Inventors: Terry L. Zarnowski, Fulton, NY (US); Karl D. Selander, Hopewell Junction, NY (US)

(73) Assignee: IoTRight, Inc., North Syraacuse, NY (US)

(21) Appl. No.: 18/242,072

(22) Filed: Sep. 5, 2023

Related U.S. Application Data
(60) Provisional application No. 63/404,248, filed on Sep. 7, 2022.

(51) Int. Cl. B01D 46/46; B01D 46/00; B01D 53/86

(52) U.S. Cl. CPC B01D 46/46; B01D 46/0086; B01D 53/8696; B01D 2255/802; B01D 2279/65

(57) ABSTRACT

A system to assess and prove the efficacy of one or more indoor air purification devices. Sensors to detect direct stimulus as to particulate and gas impurities, and collect and send the data collected from those sensors via a network to a computing device to analyze the sensor data and prove whether or not the purification devices are operating correctly. The system may also collect and analyze indirect stimulus data such as current, light intensity, temperature, humidity and air flow to prove or disprove efficacy of the purification device(s).

Priority is claimed of Provisional U.S. Patent Application Ser. No. 63/404,284, filed Sep. 7, 2022, the disclosure whereof is incorporated herein by reference.

### FIELD OF THE INVENTION

A self-testing, self-monitoring air purification system automatically optimizes the quality and purity of the air in enclosed area. This system does so by continuously monitoring the efficacy of the air purification using various sensors and software that produce actionable notifications in addition to feedback which alters the operation of the system and also reports the efficacy to building management. The system automatically adjust the operating parameters as needed to regain optimal air quality.

The purification devices might are not limited to air purification and water purification devices used to reduce or eliminate contaminants such as disease causing pathogens like viruses, bacteria, mold, and the like, but also toxic compounds such as volatile organics, dust, smoke and the like. By providing systematic sensing, monitoring and reporting from these purification devices, their efficacy can be proven.

### BACKGROUND OF THE INVENTION

In the midst of the COVID-19 pandemic of 2020 to 2022, much attention was drawn to the subject of purification technologies and the difficulty in validating their efficacy with respect to removing or eliminating contaminants inexpensively in most usage situations as well as the ability to report said efficacy in real or near real-time. In other words, it has been impossible to know how well the ruification systems are working. Commercially and economically available purification devices may be designed to eliminate contaminants but typically are neither supplied with a method of proving that such contaminants are actually being reduced or eliminated as claimed, nor has such a method been proposed for demonstrating that the device itself does not produce potentially harmful gasses during operation. For example, a high efficiency air filtration purifier is known to reduce particulate contaminants such as a virus, but does not come with a method to prove the reduction is real. In another example a purification device may employ ultra-violet (UV) light or other sterilization technology that relies on several factors in order to ensure their efficacy. Specifically, a UV purifier mounted in a Heating and Air Conditioning (HVAC) air duct may work only if: (1) There is air-flow and that air flow is at a rate, or below, for which the purifier is effective; the purifier is supplied with power; (2) the UV light source of the purifier is in good working order and is not covered with dust; and (3) In any such purification device(s) there could be a malfunction, improper installation or usage, poor maintenance or other issue that prevents the device from working as designed, and it would be necessary to know if any such condition had happened. These purification devices are not always equipped with direct measurement capabilities to measure how well the purification device is working or to validate the operation and efficacy or the purification device itself.

Recently, sensing technology has evolved to enable low cost and effective sensing of various stimuli such as measuring power usage, air flow, light intensity and the like. Moreover, technologies which test for the presence of a virus or other pathogen have not been publicly and inexpensively available until recently. As a result, it is now feasible to actually prove and report on the efficacy of any purification technology in a real-world setting, in real-time, by creating a system which incorporates continuous or periodic contaminant sensing or, in lieu of direct contaminant sensing, use of alternate stimuli sensing technologies to verify that all conditions for the applied purification technology are in the range for that purification technology to operate effectively. This is especially important since many air purification offerings today are designed to be installed in opaque and closed-off HVAC ducts and thus cannot be easily accessed, inspected, or checked on.

To prove the efficacy of purification devices, there is a critical need to provide a means of sensing and near real-time reporting on the efficacy of these devices. This can be done with ‘direct’ sensing of the contaminant(s) to be reduced or eliminated, by ‘indirect’ sensing that all of the necessary conditions exist to ensure that the employed purification technology is effective, or a combination of both direct and indirect sensing. Examples: For the direct-sensing case, detecting the reduction or absence of a previously known, present pathogen is proof that the air purification is effective; For the indirect-sensing case, one must prove that all conditions exist for a particular, already proven purification technology to correctly function, as in the UV sterilization example in which sensors confirm that the correct amount of power is being used for the UV light source, the amount of UV light flux is within manufacturer tolerance, and the air flow rate is in the effective range of the purification device. In either case, the use of sensors for monitoring allows the efficacy of the purification device to be proven or disproven.

### OBJECTS AND SUMMARY OF THE INVENTION

Accordingly, it is an object of this invention to provide a method and system to prove or disprove the efficacy of purification devices, particularly within real-world applications, through the use of one or more sensing technologies, collecting data from such sensors, applying an algorithm to analyze these data and then rendering a decision of proof through a means of reporting this decision, whether by means of a local computing device, cloud-based reporting system or other means. Proof can be determined through Direct and/or Indirect means as previously described.

In one embodiment, a system is designed to provide proof of efficacy by employing sensing technologies designed to detect one or more types of contaminants directly, for example a virus or toxic compound. As an example, a recent technology developed by Advanced Medical Solutions International, Inc. called the ‘COVID Hunter’ is a pathogen detector that can directly detect the presence of the COVID virus. This same technology in theory can be modified to detect other contaminants such as pathogens as well. This sensing technology can be applied to observe the surface of the filter of any air purifier which contains an air filter element or other surface. Data from the sensor may be sent to a cloud-based monitoring system or a local monitoring system as well. If contaminants are detected, the system will then generate an alert, report and/or other indication such as a light or audible alarm indicating and detailing such detection or alternatively indicate that no contaminant was detected. Such an embodiment might employ a second filter as well, one at the input and one at the output, such that it can be determined immediately whether the contaminants at the input of the air purifier are no longer present or reduced at the output of the device. Furthermore, additional sensors to detect other contaminants can be added to verify the correct operation of the pathogen sensor as well as monitor for other contaminants.

In another embodiment a system is designed to provide proof of efficacy by employing sensing technologies designed to detect and verify that both the environment that the purification device is installed in as well as the operational parameters of the device itself meet all of the design criteria that the purifying device is designed to operate in. For example, a purifying device may employ Photocatalytic Oxidation (PCO) technology that creates reactive oxygen compounds that are very difficult to measure directly. In this example, indirect proof might be obtained by measuring the devices power consumption, UV light intensity, air flow and humidity level. Should all of these measured factors be within the designed ranges of operation of the purifier, indirect proof of efficacy is provided. Furthermore, data from each of these sensors may be sent to a monitoring system, either local or cloud-based, which provides real-time validation of the purifier's efficacy and sends alerts to key personnel when measured parameters indicate a malfunction of any sort.

### BRIEF DESCRIPTION OF THE DRAWINGS

FIG. 1 illustrates an exemplary arrangement for proof of purification efficacy using Direct means.

FIG. 2 illustrates an exemplary arrangement proof of purification efficacy using Indirect means.

### DETAILED DESCRIPTION OF THE PREFERRED EMBODIMENT

In the following description of preferred embodiments, reference is made to the accompanying drawings which form a part hereof, and in which are shown, by way of illustration, specific embodiments that practice the invention. The person skilled in this field would understand that various other embodiments may be utilized and structural changes may be present, without departing from the scope of the present invention.

‘Purification’ devices are designed to reduce or eliminate one or more types of contaminants and can utilize different technologies to perform this purification. ‘Sensors’ are used to detect or measure one or more type of ‘Stimulus’. For proving the efficacy of purification devices, Stimulus can be defined in one of two classes, ‘Direct’ and ‘Indirect’. A Direct stimulus would be presence of the actual contaminant(s) that a purification device is designed to eliminate or reduce, for example a pathogen, or a volatile organic compound, e.g., formaldehyde. Indirect stimuli are those that are detectable and are needed for the purification device to operate effectively. These can be detected electrical current, voltage, light intensity, air flow, temperature, humidity and others. By combining the appropriate Sensor(s) with a Purification device and systematically monitoring, recording, analyzing and reporting on the data output from each sensor using a software platform, a System is created that can continuously monitor, indirectly, whether the Purification device is functioning properly, and thereby prove or disprove the efficacy of the Purification devices in near real-time.

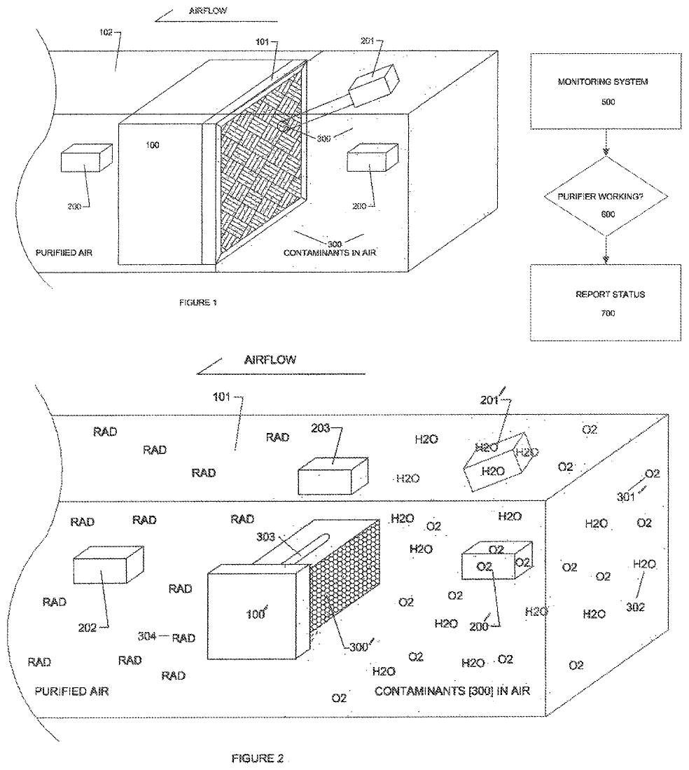

FIG. 1 illustrates a preferred embodiment of a System utilizing Sensors [200 and 201] for direct detection of Contaminants (Direct Stimulus e.g., within the airflow in a supply airduct [102]. In one embodiment, this air may be flowing through an HVAC duct or in another embodiment, the air within a room. In this illustrated embodiment, a high efficiency particulate air filter, commonly referred to as a HEPA filter, is the purification technology used by the Purification device [100]. Purification Devices that utilize HEPA filter media can be designed to filter out any contaminants (here shown as small dots in the pre-filter air) greater than a certain size by removing a percentage of those contaminants that flow through them, as specified by the manufacturer of the Purification device. Sensor 200 is designed to measure and directly detect these contaminants by counting and categorizing the size and weight, per unit volume of air, of any detectable contaminant that is in the air. Multiple Sensors can be added, for example one in the air stream before and one in the air stream after the Purification device to measure the Contaminants in the air before and also after the Purification device. A similar Sensor is used to measure particles of the Contaminant [300] trapped in the media [101]. The measurement data from these Sensors are then sent to a Monitoring System that analyzes these data, makes a decision as to whether the Purification device is working or not and reports this status, thus proving and reporting the ongoing efficacy of the Purification device. Other Sensors can also be used to measure and record other Direct Stimuli, such as the detection of a pathogen(s) on the surface of the air filter media within the Purification device. For example, if a Purification device is designed to remove a specified amount of a particular virus, a Sensor to detect that virus can be applied.

FIG. 2 shows a preferred embodiment of a System to prove the efficacy of a Purification device by using Sensors [200′, 201′, 202, 203] within an airduct that detect Indirect Stimulus or Stimuli. In this example, a Purification Device [100′] is shown that uses photocatalytic oxidation (PCO) technology. Such a device may produce gaseous hydrogen peroxide and other oxygen radicals as a reagent in the air stream, utilizing a reactor [300′] to combine oxygen and water vapor (humidity) in the surrounding air via a catalytic reaction that uses energy supplied from a light source that provides a specific wavelength or wavelengths of radiation [RAD] to the reactor [300′]. These hydrogen peroxide molecules are too difficult to detect directly as the Sensors needed to detect them are too expensive or are too difficult to apply in a given usage scenario. Thus, Sensors are used here to detect or measure the required Indirect Stimulus needed for the Purification device to operate effectively. Instead, these detectors [201′ 200′, 202 and 203] monitor Indirect Stimuli, i.e. the amount of the oxygen and or radiation [RAD] present. The data from these Sensors that detect or measure the amount of oxygen (or air containing oxygen) [301], humidity [302], and light source wavelength and intensity, send the data to a Monitoring System that analyzes this data, makes a decision about whether the Purification device is working properly or not, and reports [700] this status, thereby continuously validating the efficacy of the Purification device.

Other preferred embodiments may make use of more than one Purification device or utilize plural or several Sensors to detect both Direct and Indirect Stimulus in a System to prove overall efficacy.

The above-described and many other implementations of this invention may be practicably employed with air handling equipment or other fluid processing apparatus, without departing from the scope and spirit of the invention, as expressed in the appended claims.

We claim:

1. A system to prove the efficacy of one or more purification devices comprising sensors to detect a direct stimulus, a data collecting and processing device to which the direct stimulus data is sent from those sensors via a network and including a computing device to analyze the sensor data and report whether or not the purification devices are operating correctly.

2. The system according to claim 1, wherein said purification devices include a high performance filter that includes filter media into which intake air flows; and in which the data collecting and processing device includes at least one sensor measuring the contaminants trapped in said media, and a second sensor measuring the contaminants present in output filtered air leaving the high performance filter.

3. The system according to claim 1, wherein said purification devices include a high performance filter into which intake air flows, and in which the data collecting and processing device includes at least one sensor measuring the amount os said contaminants present in said input air ahead of said high performance filter; and a second sensor measuring the contaminants present in output filtered air leaving the high performance filter.

4. A system to prove the efficacy of one or more purification devices in which an airflow passes and is treated to neutralize a contaminant in said airflow, by employing sensors to detect indirect stimulus of said device(s), collecting and sending the data via a network from those sensors to a computing device to analyze the sensor data and prove whether or not the purification devices are operating correctly.

5. The system according to claim 4, wherein said purification devices include a reactor using radiation at a predetermined wavelength to create a reagent in said airflow, and said at least one sensor includes a sensor measuring intensity and wavelength of said radiation.

6. A system to prove the efficacy of one or more purification devices by employing sensors to detect both direct and indirect stimulus, collecting and sending the data via a network from those sensors to a computing device to analyze the sensor data and prove whether or not the purification devices are operating correctly.

7. A system according to claim 6, wherein said purification devices include a high performance filter that includes filter media into which intake air flows; and in which the data collecting and processing device includes at least one sensor measuring the contaminants trapped in said media, and a second sensor measuring the contaminants present in output filtered air leaving the high performance filter, and wherein said purification devices further include a reactor using radiation at a predetermined wavelength to create a reagent in said airflow, and said at least one sensor includes a sensor measuring intensity and wavelength of said radiation.
